(19) United States
(12) Patent Application Publication
(10) Pub. No.: US 2020/0308696 A1
(43) Pub. Date: Oct. 1, 2020

(54) Film Forming Method and Film Forming Apparatus

(71) Applicant: Tokyo Electron Limited, Tokyo (JP)

(72) Inventors: Rui KANEMURA, Nirasaki City (JP); Yoshihiro TAKEZAWA, Nirasaki City (JP); Keita KUMAGAI, Nirasaki City (JP); Keisuke FUJITA, Nirasaki City (JP)

(21) Appl. No.: 16/837,109

(22) Filed: Apr. 1, 2020

(30) Foreign Application Priority Data
Apr. 1, 2019 (JP) 2019-070114

(51) Int. Cl. C23C 16/24; C23C 16/44; C23C 16/52; H01L 21/02; C23C 16/46

(52) U.S. Cl. CPC C23C 16/24; C23C 16/4412; C23C 16/52; C23C 16/46; H01L 21/02532; H01L 21/0262; H01L 21/0243

(57) ABSTRACT

There is provided a film forming method including: supplying a halogen-free silicon raw material gas into a processing container that accommodates a substrate therein in a halogen-free silicon raw material gas supply process; supplying a halogen-containing silicon raw material gas into the processing container in a halogen-containing silicon raw material gas supply process; removing the halogen-containing silicon raw material gas inside the processing container in a halogen-containing silicon raw material gas removal process; and repeating a cycle including a sequence of the halogen-free silicon raw material gas supply process, the halogen-containing silicon raw material gas supply process, and the halogen-containing silicon raw material gas removal process in a continuous manner.

### CROSS-REFERENCE TO RELATED APPLICATION

This application is based upon and claims the benefit of priority from Japanese Patent Application No. 2019-070114, filed on Apr. 1, 2019, the entire contents of which are incorporated herein by reference.

### TECHNICAL FIELD

The present disclosure relates to a film forming method and a film forming apparatus.

### BACKGROUND

There is known a technology for forming a silicon film by supplying a silane-based gas and a silicon-based chlorine-containing compound gas to a substrate having a fine recess formed on the front surface thereof (see, for example, Patent Document 1).

### PRIOR ART DOCUMENT

### Patent Document

Patent Document 1: Japanese Laid-Open Patent Publication No. 2017-152426

### SUMMARY

According to one embodiment of the present disclosure, there is provided a film forming method including: supplying a halogen-free silicon raw material gas into a processing container that accommodates a substrate therein in a halogen-free silicon raw material gas supply process; supplying a halogen-containing silicon raw material gas into the processing container in a halogen-containing silicon raw material gas supply process; removing the halogen-containing silicon raw material gas inside the processing container in a halogen-containing silicon raw material gas removal process; and repeating a cycle including a sequence of the halogen-free silicon raw material gas supply process, the halogen-containing silicon raw material gas supply process, and the halogen-containing silicon raw material gas removal process in a continuous manner.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating a film forming method of an embodiment.

FIG. 2 is a view illustrating a gas supply sequence in the film forming method of the embodiment.

FIG. 3 is a view for explaining the effects of the film forming method of an embodiment.

FIG. 4 is a vertical cross-sectional view illustrating an exemplary configuration of a vertical heat treatment apparatus.

FIG. 5 is a view for explaining a processing container of the vertical heat treatment apparatus of FIG. 4.

FIGS. 6A to 6H are views for explaining gas supply sequences in Examples and Comparative examples.

FIG. 7 is a view representing in-plane uniformities of film thickness of silicon films formed on pattern wafers.

FIG. 8 is a view representing film thickness distributions of silicon films formed on pattern wafers.

### DETAILED DESCRIPTION

Hereinafter, non-limitative exemplary embodiments of the present disclosure will now be described with reference to the accompanying drawings. In all the accompanying drawings, the same or corresponding members or components will be denoted by the same or corresponding reference numerals, and redundant explanations thereof will be omitted. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### [Film Forming Method]

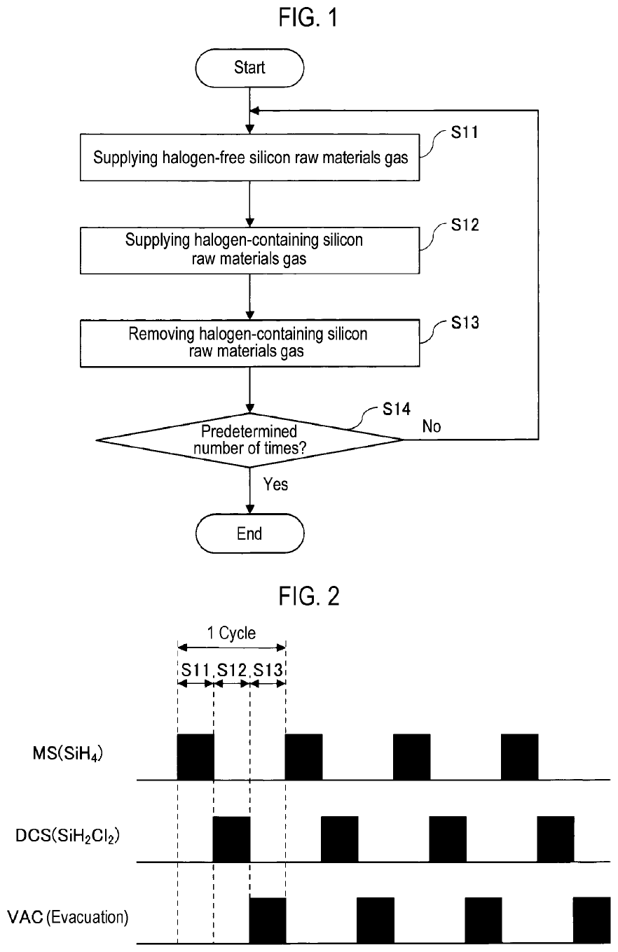

A film forming method according to an embodiment will be described. FIG. 1 is a flowchart illustrating the film forming method according to an embodiment. FIG. 2 is a view illustrating a gas supply sequence in the film forming method of the embodiment.

As illustrated in FIG. 1, the film forming method according to an embodiment includes a step of supplying a halogen-free silicon raw material gas (step S11), a step of supplying a halogen-containing silicon raw material gas (step S12), and a step S13 of removing the halogen-containing silicon raw material gas. Then, a cycle including a sequence of steps S11 to S13 is continuously repeated (step S14). Hereinafter, each step will be described.

First, a substrate is accommodated in a processing container. The halogen-free silicon raw material gas is supplied into the processing container in a state in which the interior of the processing container is depressurized and the substrate is heated (step S11). The substrate may be a substrate having a smooth front surface or a substrate having a recess, such as a trench or hole, formed on the front surface thereof. The substrate may be, for example, a semiconductor substrate such as a silicon substrate. In addition, an insulating film, such as a silicon oxide film (SiO₂ film), a silicon nitride film (SiN film) or the like, may be formed on the front surface of the substrate.

As the halogen-free silicon raw material gas, for example, an aminosilane-based gas or a hydrogenated silicon gas may be used. As the aminosilane-based gas, for example, diisopropylamino silane (DIPAS), trisdimethylamino silane (3DMAS), or bis (tertiary-butylamino) silane (BTBAS) may be used. As the hydrogenated silane gas, for example, SiH₄ (MS), Si₂H₆ (DS), Si₃H₈, or Si₄H₁₀ may be used.

Subsequently, the halogen-containing silicon raw material gas is supplied into the processing container in the state in which the substrate is heated (step S12). The step S12 of supplying the halogen-containing silicon raw material gas is performed continuously after the step S11 of supplying the halogen-free silicon raw material gas without performing evacuation and purging (gas replacement) inside the processing container. The step S12 of supplying the halogen-containing silicon raw material gas may be performed continuously, for example, after the step S11 of supplying the halogen-free silicon raw material gas while keeping the internal pressure of the processing container substantially constant. In addition, the step S12 of supplying the halogen-containing silicon raw material gas may be performed continuously, for example, after the step S11 of supplying the halogen-free silicon raw material gas and after changing the setting of the internal pressure of the processing container. In any case, the halogen-containing silicon raw material gas is supplied in the state in which the halogen-free silicon raw material gas remains in the processing container.

As the halogen-containing silicon raw material gas, for example, a fluorine-containing silicon gas, a chlorine-containing silicon gas, or a bromine-containing silicon gas may be used. As the fluorine-containing silicon gas, for example, SiF₄, SiHF₃, SiH₂F₂, or SiH₃F may be used. As the chlorine-containing silicon gas, for example, SiCl₄, SiHCl₃, SiH₂Cl₂(DCS), SiH₃Cl, or Si₂Cl₆ may be used. As the bromine-containing silicon gas, for example, SiBr₄, SiHBr₃, SiH₂Br₂, or SiH₃Br may be used.

Subsequently, the halogen-containing silicon raw material gas in the processing container is removed in the state in which the substrate is heated (step S13). In the step S13 of removing the halogen-containing silicon raw material gas, the interior of the processing container is exhausted by an exhaust device such as a vacuum pump without supplying a processing gas and a purge gas into the processing container. However, a minute amount of purge gas may be supplied into the processing container for the purpose of preventing backflow of gas to a gas supply part, a boat rotation shaft, and the like. The minute amount of purge gas corresponds to, for example, a flow rate smaller than the flow rates of the halogen-free silicon raw material gas and the halogen-containing silicon raw material gas supplied into the processing container in step S11 and step S12, respectively.

In the step S13 of removing the halogen-containing silicon raw material gas, gas replacement may be performed by, for example, exhausting the interior of the processing container using an exhaust device such as a vacuum pump or the like while supplying a replacement gas into the processing container. As the replacement gas, for example, an inert gas, H₂ (hydrogen gas), or D₂ (deuterium gas) may be used. Examples of the inert gas may include N₂ and a noble gas, such as He, Ne, or Ar.

The purpose of the step S13 of removing the halogen-containing silicon raw material gas is to remove the halogen-containing silicon raw material gas existing in the processing container, specifically on the front surface of the substrate, at the time of starting the step S11 of supplying the halogen-free silicon raw material gas, which is to be performed after step S13. Accordingly, the step S13 of removing the halogen-containing silicon raw material gas is not limited to the above method as long as it can remove the halogen-containing silicon raw material gas existing on the front surface of the substrate. For example, the step S13 of removing the halogen-containing silicon raw material gas may be a combination of the evacuation of the interior of the processing container and the supply of the replacement gas into the processing container. In the step S13 of removing the halogen-containing silicon raw material gas, it is preferable that the halogen-containing silicon raw material gas present on the front surface of the substrate be completely removed, but it is sufficient that most of the halogen-containing silicon raw material gas is removed.

Subsequently, it is determined whether or not steps S11 to S13 have been executed a predetermined number of times (step S14). If it is determined that steps S11 to S13 have been executed the predetermined number of times, the process ends. Meanwhile, if it is determined that steps S11 to S13 have not been performed the predetermined number of times, the process returns to step S11. That is, steps S11 to S13 are repeated until the predetermined number of times is reached. The predetermined number of times is determined depending a designed thickness of a silicon film to be formed.

### [Effects]

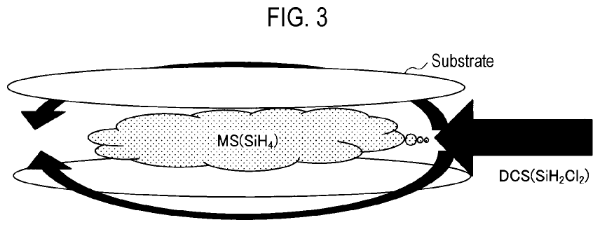

Next, the effects achieved by the film forming method of the embodiment will be described by taking as an example a case where an MS gas is used as the halogen-free silicon raw material gas and a DCS gas is used as the halogen-containing silicon raw material gas. FIG. 3 is a view for explaining the effects obtained by the film forming method of the embodiment.

For example, in a case where the MS gas and the DCS gas are supplied from the periphery of the substrate substantially parallel to the main surface of the substrate, the film thickness of the central portion of the substrate is likely to be smaller than the thickness of the peripheral portion of the substrate. It is considered that this is caused due to the fact that, when the MS gas and the DCS gas are used, the MS gas greatly contributes to the film formation and the DCS gas plays a role of suppressing the film formation.

Therefore, in the film forming method of the embodiment, after the step S11 of supplying the halogen-free silicon raw material gas into the processing container accommodating the substrate, the step S12 of supplying the halogen-containing silicon raw material gas into the processing container is continuously performed. In other words, after the step S11 of supplying the halogen-free silicon raw material gas into the processing container accommodating the substrate, the step S12 of supplying the halogen-containing silicon raw material gas into the processing container is performed without evacuating and purging the interior of the processing container. As a result, as illustrated in FIG. 3, the DCS gas is supplied into the processing container in step S12 in the state in which the MS gas supplied into the processing container in step S11 remains on the front surface of the substrate. Therefore, since the DCS gas is supplied to the peripheral portion of the substrate so as to surround the MS gas remaining in the central portion of the substrate, terminations of chlorine (Cl) to the central portion of the substrate decrease, which makes it is possible to suppress a decrease in film thickness of the central portion of the substrate. As a result, the in-plane uniformity of film thickness is improved.

In the film forming method of an embodiment, after performing the step S12 of supplying the halogen-containing silicon raw material gas into the processing container and subsequently performing the step S13 of removing the halogen-containing silicon raw material gas, the step S11 of supplying the halogen-free silicon raw material gas into the processing container is performed. Thus, in the state in which the DCS gas supplied into the processing container in step S12 is discharged from the front surface of the substrate, the MS gas is supplied into the processing container in step S11. When the DCS gas stays in the central portion of the substrate, film formation on the central portion of the substrate by the MS gas decreases. However, the present disclosure is capable of suppress such a decrease in film formation. As a result, the in-plane uniformity of film thickness is improved.

### [Film Forming Apparatus]

A film forming apparatus capable of performing the above-described film formation method will be described by taking as an example a batch-type vertical heat treatment apparatus that performs heat treatment on a large number of substrates at once. However, the film forming apparatus is not limited to the batch-type apparatus, and may be, for example, a single-wafer-type apparatus that processes substrates one by one.

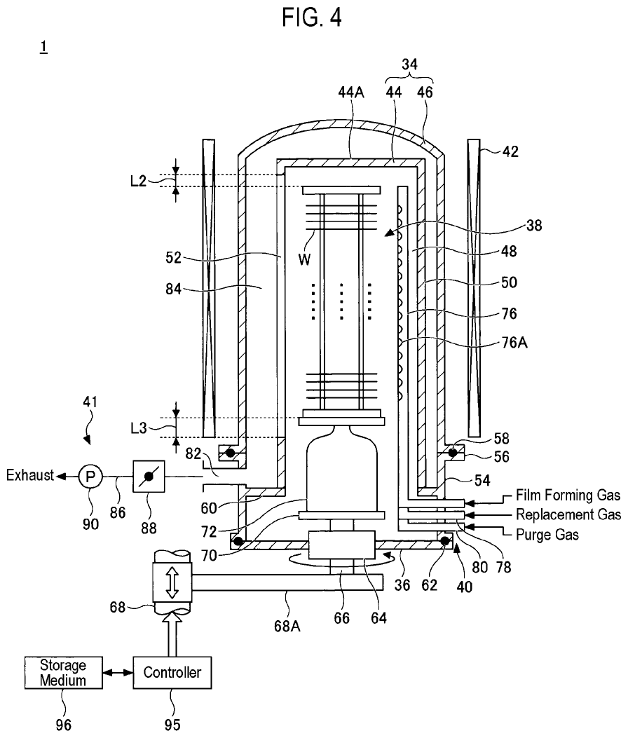

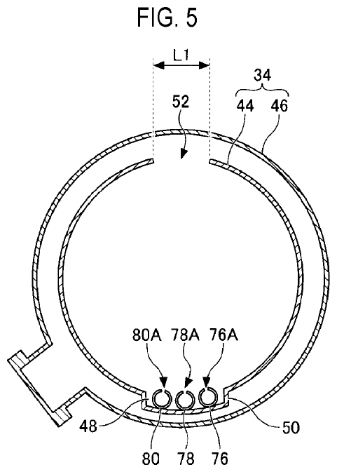

FIG. 4 is a vertical cross-sectional view illustrating an exemplary configuration of the vertical heat treatment apparatus. FIG. 5 is a view for explaining a processing container of the vertical heat treatment apparatus of FIG. 4.

As illustrated in FIG. 4, a vertical heat treatment apparatus 1 includes a processing container 34, a lid 36, a wafer boat 38, a gas supply part 40, an exhaust part 41, and a heating part 42.

The processing container 34 accommodates the wafer boat 38. The wafer boat 38 is a substrate holder that holds a large number of semiconductor wafers (hereinafter, referred to as “wafers W”) at a predetermined interval in the vertical direction in a shelf-like manner. The processing container 34 has a cylindrical inner tube 44 having a ceiling and a lower opened end, and a cylindrical outer tube 46 having a ceiling and a lower opened end and covering the outside of the inner tube 44. The inner tube 44 and the outer tube 46 are formed of a heat-resistant material such as quartz, and are arranged in a coaxial relationship with each other to have a double-tube structure.

A ceiling 44A of the inner tube 44 is, for example, flat. At one side of the inner tube 44, a nozzle accommodation portion 48 in which gas supply pipes are accommodated is formed in the longitudinal direction thereof (the vertical direction). For example, as illustrated in FIG. 5, a portion of the sidewall of the inner tube 44 protrudes outward so as to form a convex portion 50. The interior of the convex portion 50 is defined as the nozzle accommodation portion 48. In the sidewall of the inner tube 44 opposite the nozzle accommodation portion 48, a rectangular opening 52 having a width L1 is provided in the longitudinal direction thereof (the vertical direction).

The opening 52 is a gas exhaust port formed so as to be capable of exhausting the gas in the inner tube 44. A length of the opening 52 is equal to that of the wafer boat 38 or extend upward and downward in the vertical direction to be longer than the length of the wafer boat 38. That is, an upper end of the opening 52 extends such that it is located at a height equal to or higher than a position corresponding to an upper end of the wafer boat 38, and a lower end of the opening 52 extends such that it is located at a height equal to or lower than a position corresponding to a lower end of the wafer boat 38. Specifically, as illustrated in FIG. 4, a distance L2 in the height direction between the upper end of the wafer boat 38 and the upper end of the opening 52 falls within a range of about 0 mm to 5 mm A distance L3 in the height direction between the lower end of the wafer boat 38 and the lower end of the opening 52 falls within a range of about 0 mm to 350 mm.

A lower end of the processing container 34 is supported by a cylindrical manifold 54 formed of, for example, stainless steel. A flange 56 is formed on an upper end of the manifold 54. The lower end of the outer tube 46 is installed and supported on the flange 56. A seal member 58 such as an O-ring is interposed between the flange 56 and the lower end of the outer tube 46 such that the interior of the outer tube 46 is hermetically sealed.

An annular support portion 60 is provided on an inner wall of an upper portion of the manifold 54. The lower end of the inner tube 44 is installed and supported on the support portion 60. The lid 36 is hermetically installed to a lower end opening of the manifold 54 via a sealing member 62 such as an O-ring so as to hermetically close a lower end opening of the processing container 34, that is, the opening of the manifold 54. The lid 36 is formed of, for example, stainless steel.

In the central portion of the lid 36, a rotary shaft 66 is provided through a magnetic fluid seal 64. A lower portion of the rotary shaft 66 is rotatably supported by an arm 68A of an elevating part 68 including a boat elevator.

A rotary plate 70 is provided at an upper end of the rotary shaft 66. The wafer boat 38 that holds the wafers W is placed on the rotary plate 70 via a quartz heat-insulating base 72. Accordingly, by moving the elevating part 68 up and down, the lid 36 and the wafer boat 38 move vertically as a unit, so that the wafer boat 38 can be inserted into and removed from the processing container 34.

The gas supply part 40 is provided in the manifold 54, and introduces gases such as a film-forming gas, a replacement gas, and a purge gas into the inner tube 44. The gas supply part 40 has a plurality of (e.g., three) gas supply pipes 76, 78, and 80 made of quartz. Each of the gas supply pipes 76, 78, and 80 is provided within the inner tube 44 in the longitudinal direction thereof. A base end of each gas supply pipe is bent in an L shape and penetrates the manifold 54 while being supported by the manifold 54.

As illustrated in FIG. 5, the gas supply pipes 76, 78, and 80 are installed in the nozzle accommodation portion 48 of the inner tube 44 in a row in the circumferential direction. Each gas supply pipe 76, 78, or 80 has a plurality of gas holes 76A, 78A, or 80A formed at a predetermined interval in the longitudinal direction. Gases are discharged from the gas holes 76A, 78A, or 80A in the horizontal direction. Thus, the gases are supplied from the peripheries of the wafers W substantially parallel to the main surfaces of the wafers W. The predetermined interval may be set to be equal to the interval between the wafers W supported in the wafer boat 38. The positions in the height direction are set such that each of the gas holes 76A, 78A, and 80A is located in the middle between vertically adjacent wafers W, so that each gas can be efficiently supplied to spaces between the wafers W. As the types of gases, a film-forming gas, a replacement gas, and a purge gas are used. The gases can be supplied through the respective gas supply pies 76, 78, and 80, as necessary, while the flow rates thereof are controlled. Example of the film-forming gas may include the halogen-free silicon raw material gas and the halogen-containing silicon raw material gas described above. The replacement gas includes, for example, the inert gas, H₂, or D₂ described above.

A gas outlet 82 is formed in an upper sidewall of the manifold 54 above the support portion 60, so that the gas in the inner tube 44, which is exhausted from the opening 52, can be exhausted through a space portion 84 between the inner tube 44 and the outer tube 46. In the gas outlet 82, an exhaust part 41 is provided. The exhaust part 41 has an exhaust passage 86 connected to the gas outlet 82. A pressure regulation valve 88 and a vacuum pump 90 are sequentially provided in the exhaust passage 86, so that the interior of the processing container 34 can be evacuated.

On the outer circumferential side of the outer tube 46, a cylindrical heating part 42 is provided so as to cover the outer tube 46. The heating part 42 heats the wafers W accommodated in the processing container 34.

The overall operation of the vertical heat treatment apparatus 1 is controlled by a controller 95. The controller 95 may be, for example, a computer. A computer program that causes the overall operation of the vertical heat treatment apparatus 1 to be performed is stored in a non-transient storage medium 96. For example, the storage medium 96 may be a flexible disc, a compact disc, a hard disc, flash memory, a DVD or the like.

An example of the film forming method of forming an amorphous silicon film on each wafer W using the vertical heat treatment apparatus 1 will be described. First, the wafer boat 38 holding the large number of wafers W is loaded into the processing container 34 by the elevating part 68. The lower end opening of the processing container 34 is hermetically closed and sealed by the lid 36. Subsequently, the operations of the gas supply part 40, the exhaust part 41, the heating part 42, and the like are controlled by the controller 95 so as to execute the above-described film forming method. Thus, the amorphous silicon film is formed on each wafer W.

In the case where the halogen-free silicon raw material gas and the halogen-containing silicon raw material gas are supplied from the peripheries of the wafers W substantially in parallel with the main surfaces of the wafers W, a difference between film thickness in the central portion and the peripheral portion of each wafer is prone to occur. In particular, when the large number of wafers W are held at a predetermined interval in the vertical direction in the shelf-like manner, a difference in film thickness occurring between the central portion and the peripheral portion of each wafer increases as the interval decreases. Therefore, in order to reduce the difference in film thickness occurring between the central portion and the peripheral portion of each wafer, a method of increasing the interval is conceivable. However, if the interval is increased, the number of wafers W that are capable of being accommodated in the processing container decreases, which deteriorates productivity.

Therefore, in the film forming method of the embodiment, after the step S11 of supplying the halogen-free silicon raw material gas into the processing container 34 accommodating the wafers W, the step S12 of supplying the halogen-containing silicon raw material gas into the processing container 34 is continuously performed. In other words, after the step S11 of supplying the halogen-free silicon raw material gas into the processing container 34 accommodating the wafers W, the step S12 of supplying the halogen-containing silicon raw material gas into the processing container 34 is performed without evacuating and purging the interior of the processing container 34.

After performing the step S12 of supplying the halogen-containing silicon raw material gas into the processing container 34 and subsequently performing the step S13 of removing the halogen-containing silicon raw material gas inside the processing container 34, the step S11 of supplying the halogen-free silicon raw material gas into the processing container 34 is performed. Thus, in the state in which the halogen-contained silicon raw material gas supplied into the processing container 34 in step S12 is exhausted from the front surfaces of the wafers W, the halogen-free silicon raw material gas is supplied into the processing container 34 in step S11. As a result, the in-plane uniformity of film thickness of the silicon film formed on each wafer W is improved. Thus, it is possible to improve the in-plane uniformity of film thickness of the silicon film without increasing the interval. In other words, it is possible to improve the in-plane uniformity of film thickness of the silicon film without deteriorating the productivity.

### EXAMPLES

Next, examples performed to confirm the effects of the film forming method of the embodiment will be described.

First, wafers (hereinafter, also referred to as “pattern wafers”) on each of which a fine uneven pattern having a surface area ratio of 50 times or 30 times was formed was provided. The surface area ratio is a value (A1/A2) obtained by dividing a surface area A1 of a pattern wafer by a surface area A2 of a wafer on which no uneven pattern is formed (hereinafter, also referred to as a “blanket wafer”).

Subsequently, the pattern wafers were accommodated in the processing container 34 of the vertical heat treatment apparatus 1 described above. Predetermined gases were supplied into the processing container 34 according to a gas supply sequence (to be described later) to form silicon films.

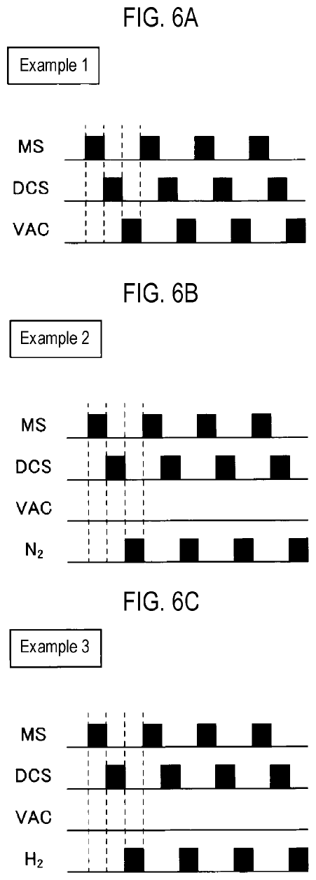

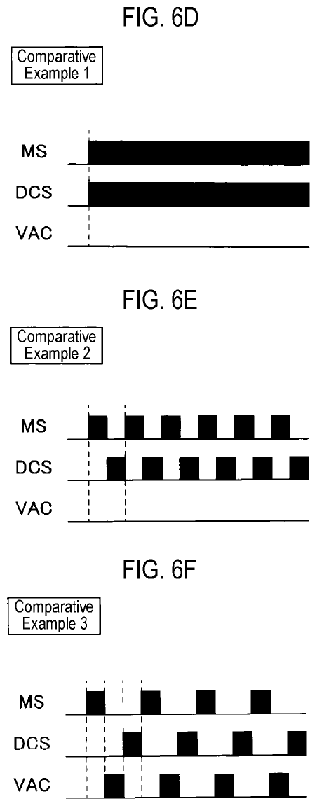

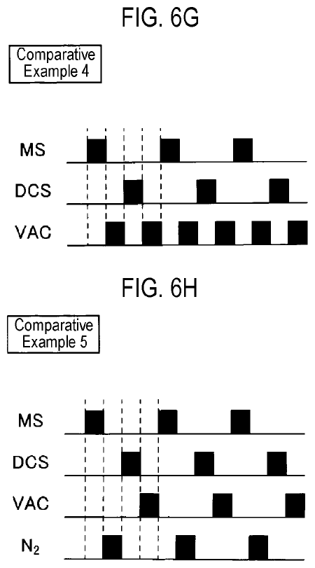

FIGS. 6A to 6H are views for explaining gas supply sequences in Examples and Comparative examples. In FIGS. 6A to 6H, “MS” represents the supply of the MS gas into the processing container, “DCS” represents the supply of the DCS gas into the processing container, “VAC” represents evacuating the interior of the processing container, “N₂” represents the supply of the N₂ gas into the processing container, and “H₂” represents the supply of the H₂ gas into the processing container. FIGS. 6A to 6C represent the gas supply sequences in Examples 1 to 3, respectively, and FIGS. 6D to 6H represent the gas supply sequences in Comparative Examples 1 to 5, respectively.

In Example 1, as represented in FIG. 6A, a silicon film was formed on the pattern wafer having the surface area ratio of 50 times by repeatedly performing the supply of the MS gas, the supply of the DCS gas, and the evacuation in this order. Processing conditions used in Example 1 are as follows.
A. Wafer temperature: 470 degrees C.
B. Processing pressure: 3 Torr (400 Pa)
C. Flow rate of MS gas: 1,500 sccm
D. Flow rate of DCS gas: 1,000 sccm
E. Supply time of MS gas/supply time of DCS gas/evacuation time: 25 seconds/30 seconds/60 seconds
F. Predetermined number of times: 170 times

In Example 2, a silicon film was formed on the pattern wafer having the surface area ratio of 30 times under the same conditions as in Example 1, except that gas replacement with the N₂ gas was performed instead of the evacuation in Example 1. That is, in Example 2, as represented in FIG. 6B, the silicon film was formed on the pattern wafer having the surface area ratio of 30 times by repeating the supply of the MS gas, the supply of the DCS gas, and the supply of the N₂ gas in this order.

In Example 3, a silicon film was formed on the pattern wafer having the surface area ratio of 30 times under the same conditions as in Example 1, except that gas replacement with the H₂ gas was performed instead of the evacuation in Example 1. That is, in Example 3, as represented in FIG. 6C, the silicon film was formed on the pattern wafer having the surface area ratio of 30 times by repeating the supply of the MS gas, the supply of the DCS gas, and the supply of the H₂ gas in this order.

In Comparative example 1, as represented in FIG. 6D, a silicon film was formed on the pattern wafer having the surface area ratio of 50 times by simultaneously supplying the MS gas and the DCS gas.

In Comparative example 2, as represented in FIG. 6E, a silicon film was formed on the pattern wafer having the surface area ratio of 50 times by alternately performing the supply of the MS gas and the supply of the DCS gas in a repetitive manner.

In Comparative example 3, as represented in FIG. 6F, a silicon film was formed on the pattern wafer having the surface area ratio of 50 times by repeating the supply of the MS gas, the evacuation, and the supply of the DCS gas in this order.

In Comparative example 4, as represented in FIG. 6G, a silicon film was formed on the pattern wafer having the surface area ratio of 50 times by repeating the supply of the MS gas, the evacuation, the supply of the DCS gas, and the evacuation in this order.

In Comparative example 5, as represented in FIG. 6H, a silicon film was formed on the pattern wafer having the surface area ratio of 50 times by repeating the supply of the MS gas, the supply of the N₂ gas, the supply of the DCS gas, and the evacuation in this order.

Subsequently, for each of the silicon films formed in Examples 1 to 3 and Comparative examples 1 to 5, the in-plane uniformity of film thickness of each silicon film was calculated by measuring film thicknesses at a plurality of locations in the plane of the wafer.

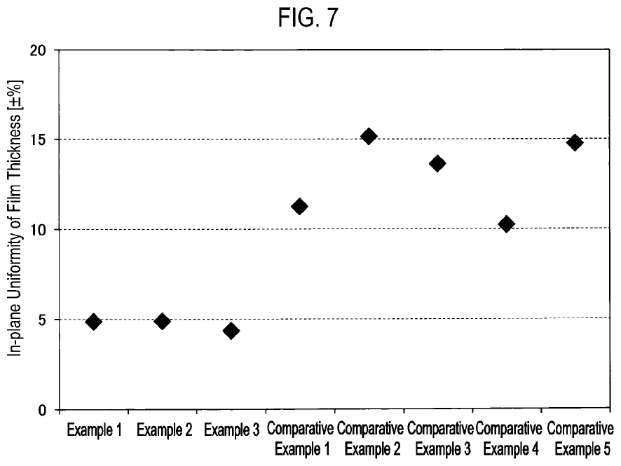

FIG. 7 is a view representing in-plane uniformities of film thicknesses of the silicon films formed on the pattern wafers. In FIG. 7, the horizontal axis represents Examples 1 to 3 and Comparative examples 1 to 5, and the vertical axis represents in-plane uniformity of film thickness [±%].

As represented in FIG. 7, the in-plane uniformities of film thicknesses in Examples 1, 2, and 3 were ±4.87%, ±4.89%, and ±4.37%, respectively. Meanwhile, the in-plane uniformities of film thicknesses in Comparative examples 1 to 5 were ±11.25%, ±15.15%, ±13.63%, ±10.24%, and ±14.76%, respectively. From these results, it can be seen that the gas supply sequences according to Examples 1 to 3 are able to improve the in-plane uniformities of film thicknesses compared with the gas supply sequences according to Comparative examples 1 to 5. That is, it can be said that, by bypassing the evacuation and the gas replacement after the supply of the MS gas and before the supply of the DCS gas, and by removing the DCS gas after the supply of the DCS gas and before the supply of the MS gas, it is possible to improve the in-plane uniformity of film thickness of the silicon film formed on each pattern wafer. That is, it can be said that, by repeating the supply of the MS gas, the supply of the DCS gas, and the removal of the DCS gas in this order, it is possible to improve the in-plane uniformity of film thickness of the silicon film formed on each pattern wafer.

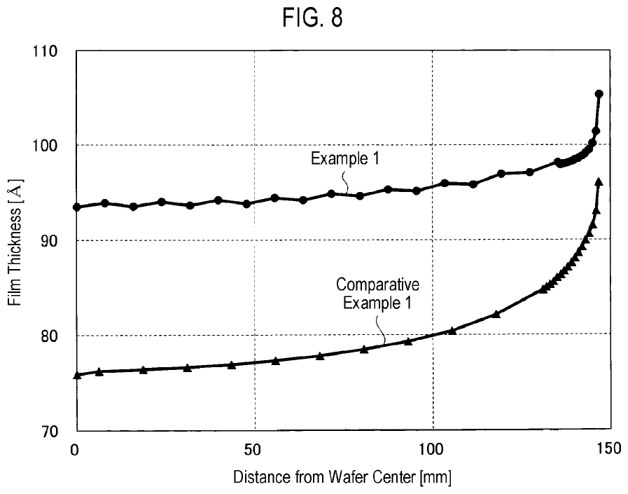

FIG. 8 is a view representing film thickness distributions in silicon films formed on pattern wafers. In FIG. 8, the horizontal axis represents a distance [mm] from a wafer center, and the vertical axis represents a film thickness [A] of a silicon film. In FIG. 8, circle (0) marks indicate the measurement results in Example 1, and triangle (1) marks represent the measurement results in Comparative example 1.

As represented in FIG. 8, it can be seen that the difference in film thickness between the central portion and the peripheral portion of the wafer in Example 1 is smaller than the difference in film thickness between the central portion and the peripheral portion of the wafer in Comparative example 1. That is, by repeating the supply of the MS gas, the supply of the DCS gas, and the evacuation in this order, it is possible to reduce the difference in film thickness between the central portion and the peripheral portion of the silicon film formed on the pattern wafer.

It should be noted that the embodiments disclosed herein are exemplary in all respects and are not restrictive. The above-described embodiments may be omitted, replaced or modified in various forms without departing from the scope and spirit of the appended claims.

In the above-described embodiments, the case where the substrate is a semiconductor wafer has been described as an example, but the present disclosure is not limited thereto. For example, the substrate may be a large substrate for a flat panel display (FPD), or a substrate for an EL element or a solar cell.

According to the present disclosure in some embodiments, it is possible to improve an in-plane uniformity of film thickness.

What is claimed is:

1. A film forming method comprising:
supplying a halogen-free silicon raw material gas into a processing container that accommodates a substrate therein in a halogen-free silicon raw material gas supply process;
supplying a halogen-containing silicon raw material gas into the processing container in a halogen-containing silicon raw material gas supply process;
removing the halogen-containing silicon raw material gas inside the processing container in a halogen-containing silicon raw material gas removal process; and
repeating a cycle including a sequence of the halogen-free silicon raw material gas supply process, the halogen-containing silicon raw material gas supply process, and the halogen-containing silicon raw material gas removal process in a continuous manner.

2. The film forming method of claim 1, wherein the halogen-free silicon raw material gas and the halogen-containing silicon raw material gas are supplied from a periphery of the substrate.

3. The film forming method of claim 1, wherein the halogen-free silicon raw material gas and the halogen-containing silicon raw material gas are supplied substantially parallel to a main surface of the substrate.

4. The film forming method of claim 1, wherein, after the halogen-free silicon raw material gas supply process, the halogen-containing silicon raw material gas supply process is continuously performed without performing an evacuation of an interior of the processing container and a gas replacement inside the processing container.

5. The film forming method of claim 1, wherein, after the halogen-free silicon raw material gas supply process, the halogen-containing silicon raw material gas supply process is performed in a state in which an internal pressure of the processing container is kept substantially constant.

6. The film forming method of claim 1, wherein, after the halogen-free silicon raw material gas supply process, the halogen-containing silicon raw material gas supply process is continuously performed while changing setting of an internal pressure of the processing container.

7. The film forming method of claim 1, wherein the halogen-containing silicon raw material gas removal process includes at least one of performing an evacuation of an interior of the processing container and performing a gas replacement inside the processing container.

8. The film forming method of claim 1, wherein the halogen-containing silicon raw material gas removal process includes performing an evacuation of an interior of the processing container.

9. The film forming method of claim 1, wherein the halogen-containing silicon raw material gas removal process includes performing a gas replacement inside the processing container.

10. The film forming method of claim 9, wherein a gas used for the gas replacement is at least one of an inert gas, a hydrogen gas, and a deuterium gas.

11. The film forming method of claim 1, wherein the substrate has a recess formed in a surface thereof.

12. The film forming method of claim 1, wherein the halogen-free silicon raw material gas is a SiH₄ gas, and the halogen-containing silicon raw material gas is a SiH₂Cl₂ gas.

13. The film forming method of claim 1, wherein a plurality of substrates are accommodated inside the processing container at a predetermined interval in a vertical direction in a shelf-like manner.

14. A film forming apparatus comprising:
a processing container in which a substrate is accommodated;
a gas supply part configured to supply a gas into the processing container; and
a controller,
wherein the controller is configured to control the gas supply part so as to continuously repeat a cycle, the cycle including a sequence of supplying a halogen-free silicon raw material gas into a processing container that accommodates a substrate therein; supplying a halogen-containing silicon raw material gas into the processing container; and removing the halogen-containing silicon raw material gas inside the processing container.
